(19) United States
(12) Patent Application Publication
(10) Pub. No.: US 2022/0255303 A1
(43) Pub. Date: Aug. 11, 2022

(54) ELECTRONIC MODULE

(71) Applicant: Sumitomo Wiring Systems, Ltd., Yokkaichi-shi, Mie (JP)

(72) Inventors: Yoshiki YANAGITA, Yokkaichi-shi, Mie (JP); Takumi EJIMA, Yokkaichi-shi, Mie (JP)

(21) Appl. No.: 17/597,805

(22) PCT Filed: Jul. 22, 2020
(86) PCT No.: PCT/JP2020/028364

§ 371 Date: Jan. 24, 2022

(30) Foreign Application Priority Data
Jul. 31, 2019 (JP) 2019-141595

(51) Int. Cl. H02G 3/16

(52) U.S. Cl. CPC H02G 3/16

(57) ABSTRACT

Provided is an electronic module for a vehicle that includes a case having an insertion hole formed therein, and a terminal that protrudes from inside the case to the outside via the insertion hole. A first protrusion portion and a second protrusion portion are respectively provided on two opposing surfaces of insertion hole.

### CROSS-REFERENCE TO RELATED APPLICATIONS

This application is the U.S. national stage of PCT/JP2020/028364 filed on Jul. 22, 2020, which claims priority of Japanese Patent Application No. JP 2019-141595 filed on Jul. 31, 2019, the contents of which are incorporated herein.

### TECHNICAL FIELD

The present disclosure relates to an electronic module provided with a case.

### BACKGROUND

Conventionally, vehicles have been equipped with an electronic module to which electronic components such as a relay are mounted.

JP 2014-79093A discloses a power supply apparatus that includes a relay provided with an openable and closable junction and an exciting coil for switching the junction to “open” or “closed”, and the power supply apparatus can use a busbar as both a current path and a heat dissipation path by electrically connecting the junction of the relay to the busbar and providing a heat dissipation mechanism in the busbar, thus making it possible to improve the heat dissipation property of the relay.

In the above-described power supply apparatus, a configuration is adopted in which an end portion of a busbar is exposed to the outside of the case via the insertion hole so as to serve as what is known as a male terminal, and is electrically connected to an external fuse, an electronic component, or the like.

However, there is a risk that, when the power supply apparatus vibrates, friction heat will be generated as a result of the male terminal and the fuse or the like sliding against each other on their contact surfaces, and electrical resistance between the busbar and the fuse or the like will increase.

In order to prevent such a problem, it is necessary to firmly fix the male terminal to the insertion hole of the case. However, it is difficult to reliably fix the male terminal due to design error, manufacturing error, or the like.

However, the power supply apparatus of JP 2014-79093A does not consider the above-described problem, and cannot solve such a problem.

In view of this, an object of the present disclosure is to provide an electronic module in which a terminal that is exposed to the outside of a case can be stably and reliably fixed.

An electronic module according to an embodiment of the present disclosure is an electronic module for a vehicle that includes a case having an insertion hole formed therein, and a terminal that protrudes from inside the case to the outside via the insertion hole, wherein a first protrusion portion and a second protrusion portion are respectively provided on two opposing surfaces of the insertion hole.

### Advantageous Effects of the Present Disclosure

According to the present disclosure, it is possible to stably and reliably fix a terminal that is exposed to the outside of a case.

### BRIEF DESCRIPTION OF DRAWINGS

FIG. 1 is a plan view of an electronic module according to a first embodiment.

FIG. 2 is a side view of the electronic module according to the first embodiment.

FIG. 3 is an illustrative diagram showing an example of a busbar attached to the electronic module according to the first embodiment.

FIG. 4 is an enlarged view of one connection portion of the electronic module according to the first embodiment.

FIG. 5 is a cross-sectional view taken along the line V-V in FIG. 4.

FIG. 6 is an enlarged view of one connection portion of an electronic module according to a second embodiment.

FIG. 7 is a cross-sectional view taken along the line VII-VII in FIG. 6.

### DETAILED DESCRIPTION OF PREFERRED EMBODIMENTS

First, embodiments of the present disclosure will be listed and described. At least some of the following embodiments may be suitably combined.

An electronic module according to an embodiment of the present disclosure is an electronic module for a vehicle that includes a case having an insertion hole formed therein, and a terminal that protrudes from inside the case to the outside via the insertion hole, wherein a first protrusion portion and a second protrusion portion are respectively provided on two opposing surfaces of the insertion hole.

According to this embodiment, the first protrusion portion and the second protrusion portion are respectively provided on two opposing surfaces of the insertion hole. Therefore, the terminal that is inserted into the insertion hole is sandwiched between the first protrusion portion and the second protrusion portion.

The electronic module according to an embodiment of the present disclosure includes a guide tube configured to guide the terminal to the insertion hole, the guide tube surrounding the insertion hole and protruding from an inner surface of the case, wherein a first tapered portion configured to guide insertion of the terminal to the guide tube is formed at a protruding end portion of the guide tube.

In this embodiment, the first tapered portion for guiding insertion of the terminal into the guide tube is formed at the protruding end portion of the guide tube. Therefore, at the time of assembly of the electronic module, insertion of the terminal into the guide tube is guided by the first tapered portion, and the terminal inserted into the guide tube is guided to the insertion hole by the guide tube, thus increasing the ease of assembly.

In the electronic module according to an embodiment of the present disclosure, a second tapered portion configured to guide insertion of the terminal into the insertion hole is formed at an end portion of each of the two opposing surfaces on an inner side of the case.

In this embodiment, the second tapered portions for guiding insertion of the terminal into the insertion hole are formed at end portions of the two opposing surfaces on the inner side of the case. Therefore, at the time of assembly of the electronic module, insertion of the terminal into the insertion hole is guided by the second tapered portions, thus increasing the ease of assembly.

In the electronic module according to an embodiment of the present disclosure, at least one first protrusion portion is provided in a portion of one of the two opposing surfaces, and a plurality of second protrusion portions are provided in portions of the other opposing surface.

In this embodiment, at least one first protrusion portion is provided in a portion of one opposing surface, and a plurality of second protrusion portions are provided in portions of the other opposing surface, and the terminal is sandwiched between the first protrusion portion and the second protrusion portions. Therefore, a similar effect can be obtained with a simpler configuration.

In the electronic module according to an embodiment of the present disclosure, the first protrusion portion and the second protrusion portions are provided so as to alternate in a direction in which the plurality of second protrusion portions are side-by-side.

In this embodiment, the first protrusion portion is provided in a portion of one opposing surface, and the plurality of second protrusion portions are provided in portions of the other opposing surface, and the first protrusion portion and the second protrusion portions are provided so as to alternate in the direction in which the plurality of second protrusion portions are side-by-side. Therefore, it is possible to secure a large distance between the first protrusion portion and the other opposing surface, and a large distance between the second protrusion portions and the one opposing surface, and it is easy to make a cast of the insertion hole.

An electronic module according to an embodiment of the present disclosure will be described below with reference to the drawings. Note that the present invention is not limited to these examples, but rather is indicated by the claims, and is intended to include all modifications that are within the meanings and the scope that are equivalent to those of the claims.

### First Embodiment

This embodiment will be described below by way of example of a vehicle electronic module on which an electronic component such as a relay is mounted.

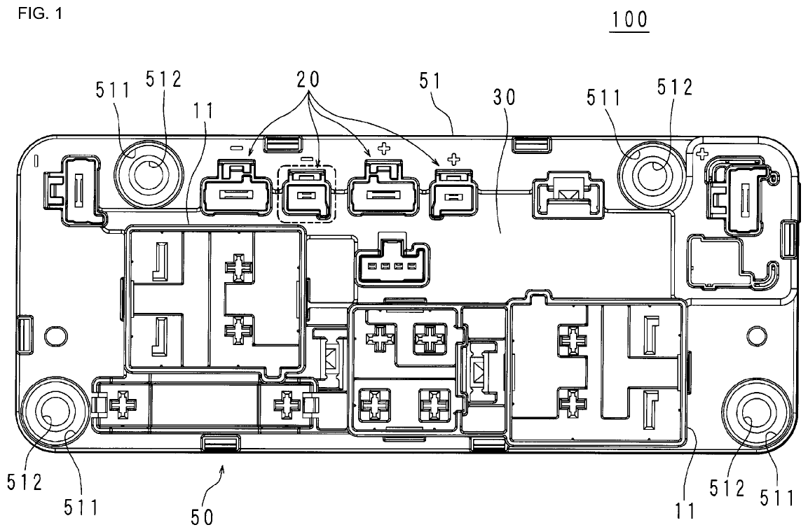

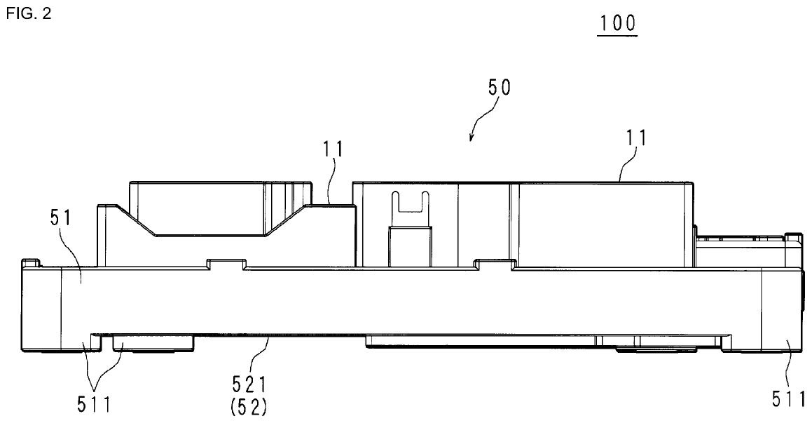

FIG. 1 is a plan view of an electronic module 100 according to the first embodiment, and FIG. 2 is a side view of the electronic module 100 according to the first embodiment.

The electronic module 100 is for attachment to the outside of a battery pack of an EV (Electric Vehicle), for example. The electronic module 100 has a case 50 in which electrical components such as a relay are mounted.

The case 50 is made of a resin, for example, and is constituted by a lower case 52 and an upper case 51 that covers the lower case 52. The case 50 is attached to a battery pack of an EV such that a bottom plate 521 of the lower case 52 faces the battery pack. More specifically, the upper case 51 includes bottomed tubular foot portions 511 provided at four sites, and through holes 512 are formed in the respective bottoms of the foot portions 511. The case 50 (the electronic module 100) can be attached to the battery pack of the EV by inserting screws into the through holes 512 of the foot portions 511 and screwing them into the battery pack, for example.

At this time, the bottom plate 521 of the lower case 52 of the electronic module 100 opposes an outer surface of the battery pack. Hereinafter, for convenience of description, the electronic module 100 side in a direction in which the electronic module 100 and the battery pack oppose each other is assumed to be an upper side, and the battery pack side is assumed to be a lower side.

The upper case 51 has the shape of a case that is open on one side, and a busbar, a circuit element, and the like are attached inside the upper case 51.

In addition, the upper case 51 includes a ceiling plate 30 that opposes the bottom plate 521 of the lower case 52. The ceiling plate 30 is substantially rectangular, and the foot portions 511 respectively protrude in a direction orthogonal to the ceiling plate 30 from the corners of the ceiling plate 30 or the vicinities of the corners.

A plurality of mount portions 11 for mounting electronic components such as a relay are provided on the outer surface of the ceiling plate 30. Specifically, the mount portions 11 are recessed portions formed in the ceiling plate 30, and rectangular tube guards are provided around the peripheral edges of the recessed portions.

A plurality of connection portions 20 for connection with an external fuse, a connector, and the like are provided on the ceiling plate 30. Each of the connection portions 20 includes a connection terminal 27, which will be described later, and the connection terminal 27 passes through the ceiling plate 30 (the case 50) from inside to outside. Accordingly, the connection terminal 27 is what is known as a male terminal.

On the inner surface of the ceiling plate 30, ribs are formed at a plurality of sites, and a plurality of mountings for attaching a busbar, a circuit element, and the like are formed. The busbar, the circuit element, and the like are attached to corresponding mountings.

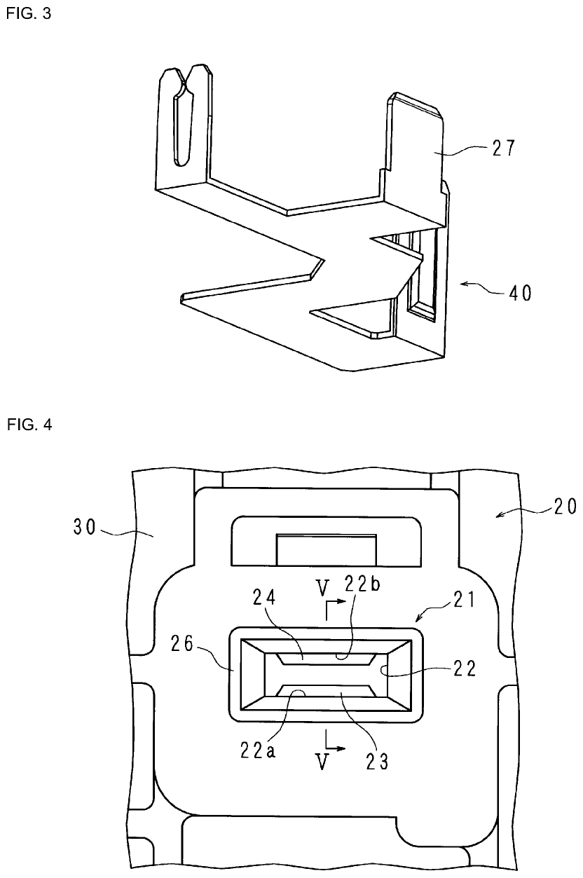

FIG. 3 is an illustrative diagram showing an example of a busbar that is attached to the electronic module 100 according to the first embodiment. A busbar 40 is made of a thin plate of a conductive metal, and a relatively large amount of current flows through the busbar 40. End portions of the busbar 40 are bent, and are orthogonal to the other part of the busbar 40. The busbar 40 is attached to a mounting of the ceiling plate 30, and, at this time, the bent end portions of the busbar 40 protrude to the outside of the case 50 via insertion holes 21, which will be described later. Accordingly, an end portion of the busbar 40 is a connection terminal 27, which is shaped like a rectangular plate. End portions of the connection terminals 27 are chamfered.

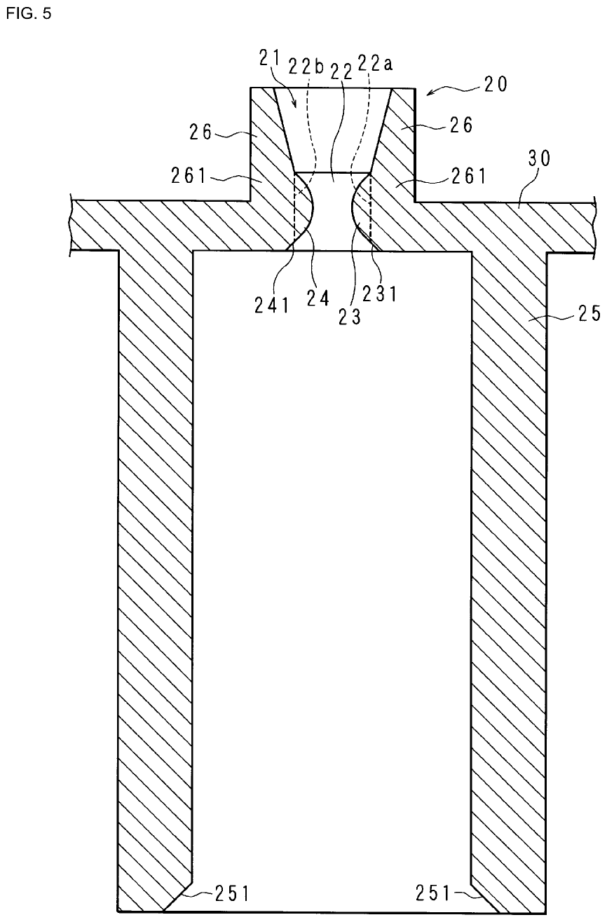

FIG. 4 is an enlarged view of one connection portion 20 of the electronic module 100 according to the first embodiment, and FIG. 5 is a cross-sectional view taken along the line V-V in FIG. 4. Specifically, FIG. 4 is an enlarged view of a portion circled by the broken line in FIG. 1.

The connection portion 20 includes the insertion hole 21.

Specifically, an elongated rectangular through hole that passes through the ceiling plate 30 in the thickness direction thereof is formed in the ceiling plate 30, and a guide 26 is provided along the outer edge of the through hole. The guide 26 has a rectangular tube shape, and protrudes from the outer surface of the ceiling plate 30. The guide 26 extends along the edge of the through hole such that the inner surface of the guide 26 is flush with the internal wall surface of the through hole of the ceiling plate 30. Accordingly, the insertion hole 21 is formed on the inner side of the guide 26. At an end portion of the guide 26 excluding a base portion 261 thereof on the ceiling plate 30 side, a tapered portion is formed on the inner surface of the guide 26, and the thickness of the guide 26 decreases toward the leading end.

When viewed in a cross-section in the direction along the outer surface of the ceiling plate 30, the base portion 261 of the guide 26 has an elongated rectangle shape, and the size of the inner side of the base portion 261 is equivalent to the size of the through hole of the ceiling plate 30. In other words, the insertion hole 21 of the connection portion 20 has a constant size in the portion from the base portion 261 of the guide 26 to the inward side of the ceiling plate 30, and increases in size at the end portion of the guide 26. The insertion hole 21 passes completely through the case 50.

A first protrusion portion 23 and a second protrusion portion 24 are respectively provided on two opposing surfaces 22a and 22b among four side surfaces 22 that form the constant-size portion, of the insertion hole 21. Specifically, the first protrusion portion 23 is provided on the opposing surface 22a corresponding to one longer side of the insertion hole 21, and the second protrusion portion 24 is provided on the opposing surface 22b corresponding to the other longer side of the insertion hole 21.

The first protrusion portion 23 and the second protrusion portion 24 are provided extending over a predetermined range on the opposing surfaces 22a and 22b excluding the two end portions thereof in the thickness direction of the ceiling plate 30. The first protrusion portion 23 and the second protrusion portion 24 protrude in the direction in which the opposing surface 22a and the opposing surface 22b oppose each other, and have a substantially semicircular shape when viewed in a vertical cross-section (see FIG. 5).

The distance between the opposing surfaces 22a and 22b is slightly larger than the thickness of the busbar 40, and the distance between the first protrusion portion 23 and the second protrusion portion 24 is slightly smaller than the thickness of the busbar 40. When attaching the busbar 40 to the case 50, the operator that is assembling the electronic module 100 according to the first embodiment press-fits the busbar 40 into the insertion hole 21, in other words between the first protrusion portion 23 and the second protrusion portion 24. Accordingly, the busbar 40 protrudes from the case 50 to the outside via the insertion hole 21. At this time, the two main surfaces of the busbar 40 abut against the first protrusion portion 23 and the second protrusion portion 24, and the busbar 40 is sandwiched therebetween.

In the electronic module 100 according to the first embodiment, due to the first protrusion portion 23 and the second protrusion portion 24 being provided in the insertion hole 21 in this manner, even when the busbar 40 requires a slight size change due to error, the issue can be addressed without changing the design, thus making it possible to prevent the case where the busbar 40 cannot be appropriately fixed due to a gap that is formed between the busbar 40 and the insertion hole 21 due to design error of the busbar 40 or design error of the connection portions 20.

Moreover, the busbar 40 does not vacillate due to vibrations from the outside, and it is possible to prevent friction heat from being generated as a result of the busbar 40 and a fuse, a connector, or the like connected to the busbar 40 sliding against each other on their contact surfaces, and to prevent the electrical resistance between the busbar 40 and the fuse, the connector, or the like from increasing.

Note that a case in which both the first protrusion portion 23 and the second protrusion portion 24 are formed has been described above as an example, but there is no limitation to this, and either only the first protrusion portion 23 or the second protrusion portion 24 may be provided.

Ceiling plate tapered portions 231 and 241 (second tapered portions) for guiding insertion of the busbar 40 are formed at the end portions of the opposing surfaces 22a and 22b on the inner side of the case 50. Specifically, the ceiling plate tapered portion 231 is formed at the inward end portion of the opposing surface 22a, and the ceiling plate tapered portion 241 is formed at the inward end portion of the opposing surface 22b.

In this manner, the ceiling plate tapered portions 231 and 241 are formed at the inward end portions of the opposing surfaces 22a and 22b of the insertion hole 21, and thus in the electronic module 100 according to the first embodiment, at the time of assembly of the electronic module 100, the busbar 40 can be easily inserted into the insertion hole 21, and the ease of assembly increases.

A guide tube 25 for guiding the busbar 40 to the insertion hole 21 at the time of assembly protrudes from the inner surface of the ceiling plate 30. The guide tube 25 has a rectangular tube shape and surrounds the insertion hole 21. Accordingly, the insertion hole 21 is in communication with the inside of the guide tube 25. Therefore, at the time of assembly of the electronic module 100, if the operator inserts the busbar 40 into the opening on the leading end side of the guide tube 25, the busbar 40 is guided to the insertion hole 21. In this manner, the guide tube 25 guides the busbar 40 to the insertion hole 21, the operator can easily insert the busbar 40 into the insertion hole 21, and the ease of assembly increases.

The guide tube 25 has a rectangular shape when viewed in a horizontal cross section, and guide tube tapered portions 251 (first tapered portions) are formed on the walls corresponding to the two longer sides. The guide tube tapered portions 251 are formed on the inner surfaces of a protruding end portion of the guide tube 25. Accordingly, in at least the end portions of the walls of the longer sides, the thickness of the guide tube 25 decreases toward the protruding end.

In this manner, the guide tube tapered portions 251 are formed on the inner surfaces of the guide tube 25 at the protruding end portion thereof, and thus, in the electronic module 100 according to the first embodiment, insertion of the busbar 40 into the guide tube 25 is guided at the time of assembly of the electronic module 100, and the ease of assembly increases.

When the operator assembles the electronic module 100, insertion of the busbar 40 into the guide tube 25 is guided by the guide tube tapered portions 251, the busbar 40 is guided to the insertion hole 21 by the guide tube 25, and insertion of the busbar 40 into the insertion hole 21 is guided by the ceiling plate tapered portions 231 and 241.

As a result of a fuse, a connector, or the like being inserted into the insertion hole 21, and fitted onto the connection terminal 27 exposed to outside of the case 50, the terminal of the fuse, the connector, or the like is electrically connected to the connection terminal 27.

### Second Embodiment

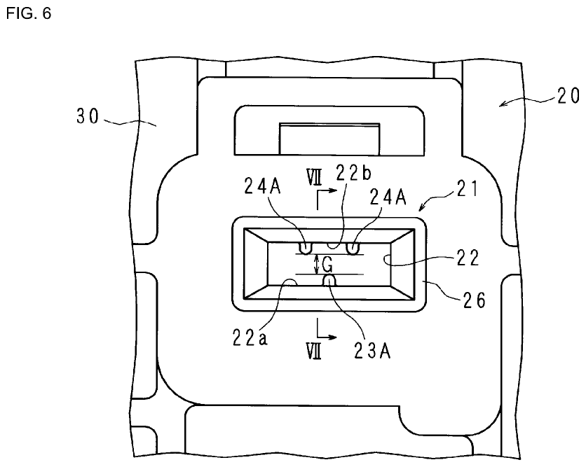

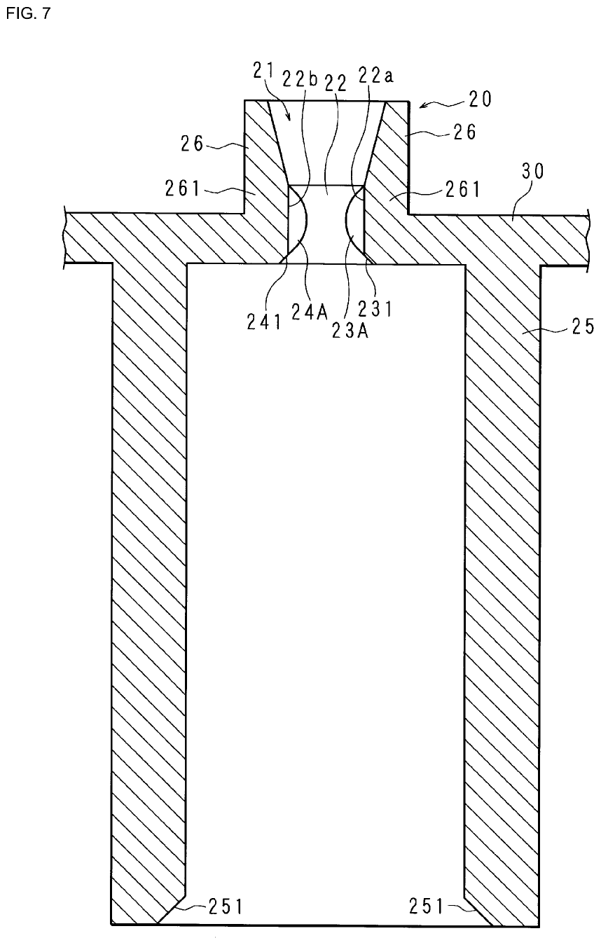

FIG. 6 is an enlarged view of one connection portions 20 of an electronic module 100 according to a second embodiment, and FIG. 7 is a cross-sectional view taken along the line VII-VII in FIG. 6.

The connection portion 20 includes an insertion hole 21 that has an elongated rectangle shape when viewed in a cross section. A guide 26 protrudes from the outer surface of the ceiling plate 30, and, similarly to the first embodiment, the insertion hole 21 is formed on the inner side of the guide 26. Tapered portions are formed on inner surfaces of the guide 26 at the end portion thereof.

The insertion hole 21 passes through the ceiling plate 30 in the thickness direction thereof. The insertion hole 21 has already been described in detail in the first embodiment, and thus a description thereof is omitted.

In the second embodiment, a first protrusion portion 23A and a second protrusion portion 24A are provided respectively on two opposing surfaces 22a and 22b among the four side surfaces 22 that form the constant-size portion, of the insertion hole 21. At least one first protrusion portion 23A is provided on the opposing surface 22a corresponding to one longer side of the insertion hole 21, and a plurality of second protrusion portions 24A are provided on the opposing surface 22b corresponding to the other longer side of the insertion hole 21. A case will be described below in which one first protrusion portion 23A is provided on the opposing surface 22a, and two second protrusion portions 24A are provided on the opposing surface 22b.

However, the electronic module 100 according to this embodiment is not limited to this, and two or more first protrusion portions 23A may also be provided, and three or more second protrusion portions 24A may also be provided.

The first protrusion portion 23A is provided in a portion at the central portion of the opposing surface 22a in the longitudinal direction of the insertion hole 21. The two second protrusion portions 24A are provided in portions of the opposing surface 22b with a predetermined distance therebetween. The first protrusion portion 23A and the second protrusion portions 24A protrude in the direction in which the opposing surface 22a and the opposing surfaces 22b oppose each other (see FIG. 7).

The distance between the opposing surfaces 22a and 22b is slightly larger than the thickness of the busbar 40, and a distance G between the first protrusion portion 23A and the second protrusion portions 24A in the direction in which the opposing surface 22a and the opposing surface 22b oppose each other is slightly smaller than the thickness of the busbar 40.

When attaching the busbar 40 to the case 50, the operator who is assembling the electronic module 100 according to the second embodiment press-fits the busbar 40 between the one first protrusion portion 23A and the two second protrusion portions 24A of the insertion hole 21. Accordingly, the busbar 40 protrudes to the outside of the case 50 via the insertion hole 21, and the busbar 40 is sandwiched between the one first protrusion portion 23A and the two second protrusion portions 24A.

Therefore, in the electronic module 100 according to the second embodiment, even when the busbar 40 requires a slight size change due to error, the issue can be addressed without changing the design, thus making it possible to prevent the case where the busbar 40 cannot be appropriately fixed due to a gap that is formed between the busbar 40 and the insertion hole 21 due to design error of the busbar 40 or design error of the connection portions 20.

The first protrusion portion 23A and the two second protrusion portions 24A are provided so as to alternate in the direction in which the two second protrusion portions 24A are side-by-side, in other words in the longitudinal direction of the insertion hole 21.

As described above, the first protrusion portion 23A is provided at the central portion of the opposing surface 22a in the longitudinal direction of the insertion hole 21. On the other hand, the two second protrusion portions 24A are provided spaced apart from the central portion of the opposing surface 22b toward the two sides in the longitudinal direction of the insertion hole 21. Accordingly, the second protrusion portions 24A are not provided at the central portion of the opposing surface 22b.

In the electronic module 100 according to the second embodiment, which has such a configuration, it is possible to secure a large distance between the opposing surface 22b and the protruding end of the first protrusion portion 23A on the opposing surface 22a, and a large distance between the opposing surface 22a and the protruding ends of the second protrusion portions 24A on the opposing surface 22b. Therefore, in a manufacturing process of the electronic module 100 according to the second embodiment, it is easy to make a cast of the insertion hole 21 (the case 50)

Note that a case in which both the first protrusion portion 23A and the second protrusion portions 24A are formed has been described above as an example, but there is no limitation to this, and either only the first protrusion portion 23A or the second protrusion portions 24A may be provided.

The ceiling plate tapered portions 231 and 241 for guiding insertion of the busbar 40 are formed at the end portions of the opposing surfaces 22a and 22b on the inner side of the case 50. The ceiling plate tapered portions 231 and 241 have already been described in detail in the first embodiment, and a description thereof is omitted.

In addition, the guide tube 25, which is for guiding the busbar 40 to the insertion hole 21 at the time of assembly, protrudes from the inner surface of the ceiling plate 30. The guide tube 25 has a rectangular shape and surrounds the insertion hole 21. In addition, the guide tube tapered portions 251 are formed at least on walls corresponding to the two longer sides of the guide tube 25. The guide tube 25 and the guide tube tapered portions 251 have been already described in detail in the first embodiment, and a description thereof is omitted here.

Constituent elements similar to those of the first embodiment are given the same reference numerals, and a detailed description thereof is omitted.

Note that a case has been described above in which the first protrusion portion 23 and the second protrusion portion 24 or the first protrusion portion 23A and the second protrusion portions 24A are provided only on the opposing surfaces 22a and 22b, but the electronic module 100 according to this embodiment is not limited to this. A configuration may also be adopted in which the first protrusion portion 23 and the second protrusion portion 24 or the first protrusion portion 23A and the second protrusion portions 24A are provided on the side surfaces adjacent to the opposing surfaces 22a and 22b, for example.

The embodiments disclosed herein are to be considered as illustrative and non-limiting in all aspects. The scope of present invention is indicated not by the above-stated meanings but by the claims, and all changes that come within the meaning and range of equivalency of the claims are intended to be embraced therein.

1. An electronic module for a vehicle that includes a case having an insertion hole formed therein, and a terminal that protrudes from inside the case to the outside via the insertion hole,
wherein a first protrusion portion and a second protrusion portion are respectively provided on two opposing surfaces of the insertion hole.

2. The electronic module according to claim 1, comprising:
a guide tube configured to guide the terminal to the insertion hole, the guide tube surrounding the insertion hole and protruding from an inner surface of the case,
wherein a first tapered portion configured to guide insertion of the terminal into the guide tube is formed at a protruding end portion of the guide tube.

3. The electronic module according to claim 2, wherein a second tapered portion configured to guide insertion of the terminal into the insertion hole is formed at an end portion of each of the two opposing surfaces on an inner side of the case.

4. The electronic module according to claim 1,
wherein at least one first protrusion portion is provided in a portion of one of the two opposing surfaces, and
a plurality of second protrusion portions are provided in portions of the other opposing surface.

5. The electronic module according to claim 4, wherein the first protrusion portion and the second protrusion portions are provided so as to alternate in a direction in which the plurality of second protrusion portions are side-by-side.

6. The electronic module according to claim 2,
wherein at least one first protrusion portion is provided in a portion of one of the two opposing surfaces, and
a plurality of second protrusion portions are provided in portions of the other opposing surface.

7. The electronic module according to claim 3,
wherein at least one first protrusion portion is provided in a portion of one of the two opposing surfaces, and
a plurality of second protrusion portions are provided in portions of the other opposing surface.
